(19) United States
(12) Patent Application Publication
(10) Pub. No.: US 2025/0059337 A1
(43) Pub. Date: Feb. 20, 2025

(54) MODIFIED POLYMER FILM AND PREPARATION METHOD THEREFOR, AND METALLIZED POLYMER FILM AND USE THEREOF

(71) Applicant: JIANGYIN NANOPORE INNOVATIVE MATERIALS TECHNOLOGY LTD, Wuxi (CN)

(72) Inventors: Zhongya ZHU, Wuxi (CN); Jianzhong XIA, Wuxi (CN); Xuefa LI, Wuxi (CN); Guoping ZHANG, Wuxi (CN)

(21) Appl. No.: 18/721,664

(22) PCT Filed: Dec. 23, 2022
(86) PCT No.: PCT/CN2022/141250

§ 371 Date: Jun. 19, 2024

(30) Foreign Application Priority Data
Dec. 23, 2021 (CN) 202111594537.1
May 24, 2022 (WO) PCT/CN2022/094626

(51) Int. Cl. C08J 7/04; B32B 15/082; B32B 15/09; B32B 15/20; B32B 27/16; B32B 27/30; B32B 27/36; C08J 7/12; C08K 3/22; C08K 5/41; C09D 7/20; C09D 7/40; C09D 7/45; C09D 7/61; C09D 7/63; C09D 129/04

(52) U.S. Cl. CPC C08J 7/0427; B32B 15/082; B32B 15/09; B32B 15/20; B32B 27/16; B32B 27/304; B32B 27/36; C08J 7/123; C09D 7/20; C09D 7/45; C09D 7/61; C09D 7/63; C09D 7/67; C09D 129/04; B32B 2250/02; B32B 2255/10; B32B 2255/26; B32B 2264/1022; B32B 2264/301; C08J 2323/12; C08J 2329/04; C08J 2367/02; C08K 2003/2241; C08K 5/41; C08K 2201/011

(57) ABSTRACT

The present invention relates to the field of film materials, in particular to a modified polymer film and a preparation method therefor, and a metallized polymer film and the use thereof. By carrying out corona treatment on the surface of a polymer layer such as polyethylene, polypropylene, polyethylene terephthalate and the like, a polar modifier can be uniformly coated on the surface of the polymer layer to form a modified layer tightly combined with the polymer layer, so that a surface of a low-polarity polymer layer is endowed with a lasting high polarity and correspondingly high surface tension, and thus can stably and tightly combine with a metal layer and other high-polarity high-surface-tension material layers for a long time, effectively expanding usage scenarios of a non-polar polymer substrate layer. The preparation method features a simple and feasible treatment process, low cost, high treatment efficiency and easy expansion. The surface tension of a prepared modified polymer film can be 68 mN/m, and will not obviously reduce after the film is stored for three months.

### TECHNICAL FIELD

The present disclosure generally relates to a field of film materials, and in particular, to a modified polymer film and a preparation method therefor, and a metallized polymer film and a use thereof.

### BACKGROUND

Since metallized polymer films can be widely used in packaging, printing, electronics and other fields, the metallized polymer films have attracted much attention from the industry. In related art, metal is deposited directly on the surface of polymer films such as polypropylene, polyethylene, and polyester by physical vapor deposition techniques to prepare the metallized polymer films. However, polarities of the polymer films are weak, resulting in a low surface tension of the polymer films. The affinity between the polymer film with a low surface tension and the metal material with a high surface tension is poor, which results in a low adhesion between an interface of the polymer film and an interface of the metal material and thus a bond between the polymer film and the metal material is weak. In order to solve this problem, a corona treatment on the surface of the polymer film is performed to increase the surface tension of the polymer film, thus enhancing bonding strength between polymer films and the metal materials.

However, the method of corona treatment has many shortcomings, which are shown hereinafter. (1) Under the premise of the mechanical properties of the polymer film do not change significantly, the surface tension of the polymer film after corona treatment is generally in a range of 30 mN/m to 45 mN/m. Compared with the surface tension of the polymer films before the corona treatment (in a range of 20 mN/m to 30 mN/m), the improvement of the surface tension of the polymer films after the corona treatment is limited. Thus, the gap between the surface tension of the polymer films after the corona treatment and the surface tension of the metal materials (greater than 100 mN/m) remains relatively large, leading to an unideal bond between the two. (2) The surface tension of the polymer films after the corona treatment is not stable. After storage for a period of time, the surface tension decreases, and finally approaches the surface tension of the polymer films before the treatment.

### SUMMARY

In view of above, it is necessary to provide a modified polymer film and a preparation method therefor. A surface tension on a surface of the modified polymer film can be maintained for a long time without affecting mechanical properties of the modified polymer film. Thus, the modified polymer film can achieve long-term stable bonding with a metal layer having a high surface tension, thereby producing high performance metallized polymer film.

In an aspect of the present disclosure, a method for preparing the modified polymer film is provided, which includes the following steps:
providing a polymer layer, and subjecting the polymer layer to a corona treatment to obtain a corona treated polymer layer: and coating a modifier on a surface of the corona treated polymer layer, and drying to form a modified layer;
in which, a material of the polymer layer is one or more selected from polyethylene, polypropylene, polyethylene terephthalate, polybutylene terephthalate, polyethylene naphthalate, polyvinyl chloride, polyvinylidene fluoride, and polyphenylene sulfide.

The modifier comprises a component A and a component B, which are prepared separately. The component A is an aqueous solution of polyvinyl alcohol having 0.2% to 2% by mass of polyvinyl alcohol: optionally, an aqueous solution of polyvinyl alcohol having 0.5% to 1.5% by mass of polyvinyl alcohol. The polyvinyl alcohol in the polyvinyl alcohol aqueous solution has an alcoholysis degree in a range of 95% to 100%. The component B is an aqueous solution of a cross-linking agent having 0.2% to 2% by mass of the cross-linking agent: optionally, an aqueous solution of a cross-linking agent having 1.0% to 2.0% by mass of the cross-linking agent. The cross-linking agent can be one or more selected from glyoxal, malondialdehyde, butanedial, glutaraldehyde, hexanedial, heptanedial, and octanedial.

In some embodiments, in a step of coating the modifier on the surface of the corona treated polymer layer, the ratio of a feeding amount of the component A to a feeding amount of the component B is in a range of 1:4 to 4:1.

In some embodiments, the component A further includes 0.001% to 0.2% by mass of inorganic nano-particles: optionally, 0.005% to 0.15% by mass of inorganic nano-particles: optionally, 0.01% to 0.1% by mass of inorganic nano-particles. The inorganic nano-particles are one or more selected from titanium dioxide, silicon dioxide, and graphene oxide.

In some embodiments, the component A further comprises 0.001% to 0.1% by mass of a surfactant, and the surfactant is one or more selected from sodium dodecyl sulfate, sodium dodecyl sulfonate, Tween® 20, and Tween® 80.

In some embodiments, a pH value of the component B is in a range of 0.8 to 3; preferably, the pH value of the component B is in a range of 0.8 to 2; more preferably, the pH value of the component B is in a range of 0.8 to 1.5.

In some embodiments, an average particle size of the inorganic particles is in a range of 5 nm to 15 nm.

In some embodiments, a weight-average molecular weight of the polyvinyl alcohol is in a range of 50000 Da to 150000 Da.

In some embodiments, in a step of coating the modifier on the surface of the corona treated polymer layer, a coating thickness of the modifier is in a range of 20 μm to 200 μm.

In some embodiments, in a step of coating the modifier on the surface of the corona treated polymer layer, the thickness of the formed modified layer is in a range of 20 nm to 200 nm.

In some embodiments, a time interval between a step of coating the modifier on the surface of the corona treated polymer layer and a step of drying is in a range of 0 to 120 seconds; preferably, the time interval between the step of coating the modifier on the surface of the corona treated polymer layer and the step of drying is in a range of 20 seconds to 60 seconds.

In some embodiments, a step of drying is a heating treatment, a temperature of the heating treatment is in a range of 60° C. to 90° C., and a time of the heating treatment is in a range of 0.01 min to 5 min.

In some embodiments, a step of coating the modifier on the surface of the corona treated polymer layer comprises: loading the component A and the component B into different feeding devices, respectively, and feeding the component A and the component B synchronously from the respective feeding devices at a rate of 50 mL/min to 200 mL/min for coating.

In some embodiments, in a step of subjecting the polymer layer to a corona treatment to form a corona treated polymer layer, a power of the corona treatment is in a range of 10 kW to 30 kW, a current of the corona treatment is in a range of 4 A to 10 A, and a linear velocity of the corona treatment is in a range of 50 m/min to 200 m/min.

In another aspect of the present disclosure, a modified polymer film is provided herein, and the modified polymer film is prepared according any one of the methods described herein.

In another aspect of the present disclosure, a metallized polymer film is provided herein. The metallized polymer film includes the modified polymer film described herein, and a metal layer disposed on a modified layer of the modified polymer film. A material of the metal layer can be selected from copper, aluminum, nickel, chromium, titanium, molybdenum, tungsten, nickel-chromium alloys, nickel-chromium-aluminum alloys, nickel-copper alloys, and titanium-aluminum alloys.

The present disclosure further provides use of the metallized polymer film described herein in preparing packaging materials, printing products or electronic components.

By subjecting the surface of the polymer layers such as polyethylene, polypropylene, polyethylene terephthalate, etc., to corona treatment, polar modifiers are uniformly coated on the surface of the polymer layer. Thus, a modified layer that is tightly bonded to the polymer layer is prepared, giving the low-polarity polymer layer a long-lasting high polarity on its surface and a correspondingly high surface tension. Thus, the polymer layer is able to bond closely and stably with high surface tension material layers, such as a metal layer and the like, for a long time, effectively broadening uses of non-polar polymer substrate layers. By controlling the concentration of each component in the modifier and controlling the alcoholysis degree of the polyvinyl alcohol, a suitable cross-linking density of the modified layer formed after the cross-linking reaction can thus be achieved. In the case of controlling the thickness of the modified layer, the surface of the modified layer is still made to have uniform and stable properties with a sufficiently high number of hydroxyl groups, so that the polarity and surface tension of the polymer layer in the long term can be more effectively and stably enhanced. The preparation method is simple, has a low cost and high efficiency, and is easy to scale up. The surface tension of the modified polymer film can be as high as 68 mN/m. In addition, the surface tension of the modified polymer film will not decrease significantly after three months, which can effectively promote the strong bond between the non-polar polymer layer and the polar material layer such as the metal layer, and realize stable subsequent processing.

### DETAILED DESCRIPTION

In order to facilitate an understanding of the present disclosure, the present disclosure will be described more fully below with reference to relevant embodiments. However, the present disclosure can be realized in many different forms and is not limited to the embodiments described herein. Rather, these embodiments are provided to enable a more thorough and comprehensive understanding of the disclosure of the present disclosure.

Furthermore, the terms “first” and “second” are used for descriptive purposes only and are not to be understood as indicating or implying relative importance or implicitly specifying the number of technical features indicated. Thus, a feature defined with the terms “first”, “second” may expressly or implicitly include at least one such feature. In the description of the present disclosure, “a plurality of” means at least two, e.g., two, three, etc., unless otherwise expressly and specifically limited. In the description of the present disclosure, “several” means at least one, e.g., one, two, etc., unless otherwise expressly and specifically limited.

Unless otherwise defined, all technical and scientific terms used herein have the same meaning as commonly understood by those skilled in the art of the present disclosure. Terms used herein in the specifications of the present disclosure are used only for the purpose of describing specific embodiments and are not intended to limit the present disclosure. The term “and/or” as used herein includes any and all combinations of one or more of the relevant listed items.

In the present disclosure, technical features described in an open-ended manner include closed technical solutions including the enumerated features, as well as open-ended technical solutions including the enumerated features.

In the present disclosure, a numerical interval is involved. Unless otherwise specified, the above numerical interval is considered to be continuous within the range of values and includes a minimum value and a maximum value of the range, as well as each of the values between such minimum and maximum values. Furthermore, when the range refers to an integer, each integer between the minimum and maximum values of the range is included. In addition, when multiple ranges are provided to describe a characteristic or feature, the ranges may be combined. In other words, unless otherwise indicated, all ranges disclosed herein should be understood to include any and all sub-ranges subsumed therein.

Compositions expressed in percentage, as it relates to the present disclosure, if not otherwise indicated, refers to mass percentage for both solid-liquid mixing and solid-phase-solid-phase mixing, and to volume percentage for liquid-phase-liquid-phase mixing.

The percentage concentrations involved in the present disclosure, if not otherwise specified, refer to the final concentration. The final concentration refers to the percentage of the added component in the system to which the component has been added.

The temperature parameters involved in the present disclosure, if not specifically limited, allow for both constant temperature treatments and treatments within certain temperature intervals. The constant temperature treatment allows the temperature to fluctuate within the accuracy of the instrumental control.

In the present disclosure, the “molecular weight” of the polymer is understood to be the weight-average molecular weight, and the average molecular weight is the weight-average molecular weight if not otherwise specified.

In an aspect of the present disclosure, a method for preparing a modified polymer film is provided, which includes the following steps:
providing a polymer layer, and subjecting the polymer layer to a corona treatment to form a corona treated polymer layer: and coating a modifier on a surface of the corona treated polymer layer, and drying to form a modified layer.

In the steps, a material of the polymer layer is selected from polyethylene, polypropylene, polyethylene terephthalate, polybutylene terephthalate, polyethylene naphthalate, polyvinyl chloride, polyvinylidene fluoride, and polyphenylene sulfide.

The modifier includes a component A and a component B, which are separately prepared. The component A is an aqueous solution of polyvinyl alcohol having 0.2% to 2% by mass of polyvinyl alcohol. The polyvinyl alcohol in the aqueous solution of polyvinyl alcohol has an alcoholysis degree in a range of 95% to 100%. The component B is an aqueous solution of a cross-linking agent having 0.2% to 2% by mass of a cross-linking agent. The cross-linking agent is one or more selected from glyoxal, malondialdehyde, butanedial, glutaraldehyde, hexanedial, heptanedial, and octanedial.

Polymers, such as polyethylene, polypropylene, polyethylene terephthalate, polybutylene terephthalate, polyethylene naphthalate, polyvinyl chloride, polyvinylidene fluoride and polyphenylene sulfide, can be used to prepare a biaxially oriented polymer film. Due to the fixed orientation of the stretched molecules, the polymer films exhibit good physical stability, good mechanical strength and airtightness, high transparency and gloss, and are tough and wear-resistant, and thus are widely used in fields of packaging, printing, electronics, and the like. However, the polymers have low polarity and therefore low surface tension, which makes the polymer difficult to stably compound with materials with high surface tension, such as metals, to form film materials with diverse properties. To solve the problem, researchers have developed the surface treatment method of corona treatment to enhance the polarization and surface tension of the surface of the polymer films. However, the enhancement of surface tension of the polymer films by corona treatment is limited and the treated surface tension cannot be maintained for a long period of time, so use of the corona treated polymer films is still very limited.

In view of the problems above, after extensive research, the inventor has found that introduction of a polar modifier, supplemented by a suitable process for modifying the surface of the polymers, can solve the problems existing in the related art. By subjecting the surface of the polymer films to corona treatment, polar modifiers are uniformly coated on the surface of the polymer films, and thereby forms a modified layer which is tightly bonded to the polymer layer, and thus provides a long-lasting high polarity and hence a high surface tension at the surface of the low-polarity polymer layer. Thus, the polymer layer is able to bond closely and stably with high surface tension material layers, such as a metal layer and the like, for a long time, effectively broadening uses of non-polar polymer substrate layers. By controlling the concentration of each component in the modifier and controlling the alcoholysis degree of the polyvinyl alcohol, the modified layer formed after the cross-linking reaction has a suitable cross-linking density and a sufficiently high number of hydroxyl groups, so that the polarity and surface tension of the polymer layer in the long term can be more effectively and stably enhanced. The preparation method is simple, has a low cost and high efficiency, and is easy to scale up. The surface tension of the modified polymer film can be as high as 68 mN/m. In addition, the surface tension of the modified polymer film will not decrease significantly after three months, which can effectively promote the combination between the non-polar polymer layer and the polar material layer such as the metal layer, and realize the stability of the subsequent processing.

Optionally, the polymer layer is prepared by a biaxially oriented processing. Furthermore, the polymer layer is prepared by fusing-extruding biaxially oriented processing.

Optionally, a thickness of the polymer layer is larger than or equal to 4 μm. The thickness of the polymer layer can be selected from 4.5 μm, 6 μm, 8 μm, 10 μm, 20 μm and the like.

Optionally, the polyvinyl alcohol in the component A can be of 0.3%, 0.4%, 0.5%, 0.6%, 0.7%, 0.8%, 0.9%, 1%, 1.1%, 1.2%, 1.3%, 1.4%, 1.5%, 1.6%, 1.7%, 1.8% or 1.9% by mass.

Optionally, the cross-linking agent in the component B can be of 0.3%, 0.4%, 0.5%, 0.6%, 0.7%, 0.8%, 0.9%, 1%, 1.1%, 1.2%, 1.3%, 1.4%, 1.5%, 1.6%, 1.7%, 1.8% or 1.9% by mass.

Optionally, the alcoholysis degree of the polyvinyl alcohol can be 96%, 97%, 98% or 99%.

In a step of coating the modifier on the surface of the corona treated polymer layer, a ratio of a feeding amount of the component A to a feeding amount of the component B is in a range of 1:4 to 4:1. Preferably, a ratio of a feeding amount of the component A to a feeding amount of the component B is 1:1.

The polyvinyl alcohol having a high alcoholysis degree can provide sufficient hydroxyl groups, so that the surface tension of the modified polymer film is greater. At the same time, by controlling the mass percentage the polymer alcohol and the cross-linking agent in a suitable range, the reaction can process smoothly and under control, so as to avoid preparing an uneven modified layer resulted by uncontrollable reaction.

Preferably, the cross-linking agent is selected from glutaraldehyde. A raw material of the glutaraldehyde has a low cost, high stability, high safety, and higher reactivity with the polyvinyl alcohol.

In some embodiments, the component A further comprises 0.001% to 0.2% by mass of inorganic nano-particles. The inorganic nano-particles are one or more selected from titanium dioxide, silicon dioxide, and graphene oxide. The modified layer includes the inorganic nano-particles described herein, which can improve roughness of the modified layer, preventing films from adhering with each other and improving adhesion stress between the modified layer and the metal layer. In addition, the inorganic nano-particles are hydrophilic particles, therefore further improving the surface tension of the modified layer. Optionally, the inorganic nano-particles can be of 0.01%, 0.02%, 0.03%, 0.04%, 0.05%, 0.06%, 0.07%, 0.08%, 0.09%, 0.1%, 0.11%, 0.12%, 0.13%, 0.14%, 0.15%, 0.16%, 0.17%, 0.18% or 0.19% by mass. Suitable inorganic nano-particles having a suitable percentage composition can facilitate uniform dispersion of the inorganic nano-particles in the modified layer, thereby better functioning.

In some embodiments, the component A further includes 0.001% to 0.1% by mass of a surfactant, and the surfactant is selected from dodecyl sodium sulfate, sodium dodecyl sulfonate, Tween® 20, and Tween® 80. The surfactant enables better dispersion of high alcoholysis degree polyvinyl alcohol in water better, so as to better participate in the subsequent cross-linking reaction.

In some embodiments, a pH value of the component B is in a range of 0.8 to 3. Optionally, the pH value of the component B can be 0.85, 0.9, 0.95, 1, 1.05, 1.1, 1.15, 1.2, 1.25, 1.3, 1.35, 1.5, 1.75, 2, 2.25 or 2.75. By controlling the pH value of the component B in a range of 0.8 to 3, an acidic environment can be provided to the reaction between the polyvinyl alcohol and the cross-linking agent, thereby facilitate improved reaction rate of the cross-linking reaction. When the pH value is too high or too low, the reaction may be difficult, which results in low cross-linking degree of the modified layer, thereby affecting long-term stability of the modified layer.

In some embodiments, the pH value of the component B can be controlled by adding an acid. Optionally, the pH value of the component B can be controlled by concentrated sulfuric acid or concentrated hydrochloric acid. Optionally, the concentrated sulfuric acid or the concentrated hydrochloric acid can be in a range of 0.2% to 0.5% by mass, in the component B: optionally, the concentrated sulfuric acid or the concentrated hydrochloric acid can be 0.3% or 0.4% by mass, in the component B.

In some embodiments, an average particle size of the inorganic particles is in a range of 5 nm to 15 nm. Optionally, the average particle size of the inorganic particles can be 6 nm, 8 nm, 10 nm, 12 nm or 14 nm. The inorganic particles having suitable particle sizes can be well dispersed in the modifier, and improve a surface roughness of the modified layer well.

In some embodiments, a weight-average molecular weight of the polyvinyl alcohol is in a range of 50000 Da to 150000 Da. Optionally, the weight-average molecular weight of the polyvinyl alcohol can be 60000 Da, 70000 Da, 80000 Da, 90000 Da, 100000 Da, 110000 Da, 120000 Da, 130000 Da or 140000 Da. In a preset range of weight-average molecular weight, the polyvinyl alcohol not only has good film-forming ability, but also has good solubility. Thus, the modifier can be coated uniformly, and the modified layer has better performances.

In some embodiments, in a step of coating the modifier on the surface of the corona treated polymer layer, a coating thickness of the modifier is in a range of 20 μm to 200 μm. Optionally, the coating thickness of the modifier can be 25 μm, 30 μm, 35 μm, 40 μm, 45 μm, 50 μm, 55 μm, 60 μm, 65 μm, 70 μm, 75 μm, 80 μm, 85 μm, 90 μm, 105 μm, 110 μm, 115 μm, 120 μm, 125 μm, 130 μm, 135 μm, 140 μm, 145 μm, 150 μm, 155 μm, 160 μm, 165 μm, 170 μm, 175 μm, 180 μm, 185 μm, 190 μm or 195 μm. Providing the modifier having the coating thickness in a suitable range, in combination with the specific formulation of the modifier, and applying moderate amount and moderate viscosity of the modifier, can thus achieve uniform coating, and the modified layer having a suitable thickness can be formed after drying.

In some embodiments, the thickness of the formed modified layer is in a range of 20 nm to 200 nm. Optionally, the thickness of the modified layer can be 25 nm, 30 nm, 35 nm, 40 nm, 45 nm, 50 nm, 55 nm, 60 nm, 65 nm, 70 nm, 75 nm, 80 nm, 85 nm, 90 nm, 105 nm, 110 nm, 115 nm, 120 nm, 125 nm, 130 nm, 135 nm, 140 nm, 145 nm, 150 nm, 155 nm, 160 nm, 165 nm, 170 nm, 175 nm, 180 nm, 185 nm, 190 nm or 195 nm. Once the modifier has a coating thickness in the suitable range, the polarity and the surface tension of the polymer substrate layer can be effectively improved, and thus avoid affecting the thickness or physical properties of the substrate layer.

In some embodiments, a time interval between a step of coating the modifier on the surface of the corona treated polymer layer and a step of drying is in a range of 0 to 120 seconds. Optionally, the time interval between the step of coating the modifier on the surface of the corona treated polymer layer and the step of drying can be 5 s, 10 s, 15 s, 20 s, 25 s, 30 s, 35 s, 40 s, 45 s, 50 s, 55 s, 60 s, 65 s, 70 s, 75 s, 80 s, 85 s, 90 s, 95 s, 100 s, 105 s, 110 s or 115 s. Assuring a certain period of extra preset reaction time between the step of coating the modifier on the surface of the corona treated polymer layer and the step of drying can achieve a more ideal cross-linking degree, so that the formed modified layer can be more stable.

In some embodiments, drying is achieved by a heating treatment, and a temperature of the heating treatment is in a range of 60° C. to 90° C., while a time of the heating treatment is in a range of 0.01 min to 5 min. Optionally, the temperature of the heating treatment can be 65° C., 70° C., 75° C., 80° C. or 85° C.; and the time of the heating treatment can be 1 min, 2 min, 3 min or 4 min.

In some embodiments, a step of coating the modifier on the surface of the corona treated polymer layer includes: separately loading the component A and the component B into different feeding devices, respectively, and feeding the component A and the component B synchronously from the respective feeding devices at a rate of 50 mL/min to 200 mL/min for coating. Optionally, the feeding rate of the component A and the component B can be 55 mL/min, 60 mL/min, 65 mL/min, 70 mL/min, 75 mL/min, 80 mL/min, 85 mL/min, 90 mL/min, 95 mL/min, 100 mL/min, 105 mL/min, 110 mL/min, 115 mL/min, 120 mL/min, 125 mL/min, 130 mL/min, 135 mL/min, 140 mL/min, 145 mL/min, 150 mL/min, 155 mL/min, 160 mL/min, 165 mL/min, 170 mL/min, 175 mL/min, 180 mL/min, 185 mL/min, 190 mL/min or 195 mL/min. By providing a suitable feeding rate of the component A and a suitable feeding rate of the component B, the cross-linking reaction processes better and the modifier is coated more uniformly.

In some embodiments, the modifier is coated by a extruding-coating process with a slit-type die head.

In some embodiments, in a step of subjecting the polymer layer to a corona treatment to form a corona treated polymer layer, a power of the corona treatment is in a range of 10 KW to 30 KW, a current of the corona treatment is in a range of 4 A to 10 A, and a linear velocity of the corona treatment is in a range of 50 m/min to 200 m/min. Optionally, the power of the corona treatment can be 15 KW, 20 KW or 25 KW. Optionally, the current of the corona treatment can be 6 A or 8 A. Optionally, the linear velocity of the corona treatment can be 75 m/min, 100 m/min, 125 m/min, 150 m/min or 175 m/min. The corona treatment can initially improve the surface tension of the polymer layer, so that the water-based modifier can uniformly be coated on the surface of the polymer layer. Thus, the modified layer finally formed can be tightly and stably bond to the polymer layer. Suitable parameters of the corona treatment adapt better to the modified formulation in the present disclosure.

In some embodiments, the preparation of the component A includes the following steps:
adding polyvinyl alcohol in water at room temperature, stirring and soaking the polyvinyl alcohol for 1 hour to 2 hours, heating the resultant in an oil bath of 80° C. to 100° C. after the soaking, and stirring until the polyvinyl alcohol are totally dissolved: optionally, heating the resultant in a 90° C. oil bath: and
adding a surfactant into the polyvinyl alcohol solution, stirring until the surfactant are totally dissolved, then adding inorganic nano-particles into the resultant, mechanically stirring for 20 min to 40 min, and ultrasonically dispersing in an ultrasonic cleaner at room temperature for 50 min to 70 min: and optionally, mechanically stirring for 30 min, and ultrasonically dispersing for 60 min.

In some embodiments, a rotate speed of the mechanical stirring is in a range of 100 rpm to 1000 rpm. Preferably, the rotate speed of the mechanical stirring is 500 rpm.

In some embodiments, power of the ultrasonic dispersion is in a range of 500 W to 700 W, and a frequency of the ultrasonic dispersion is in a range of 35 kHz to 45 kHz. Preferably, the power of the ultrasonic dispersion can be 600 W, and the frequency of the ultrasonic dispersion can be 40 kHz. The ultrasonic dispersion can facilitate dispersion of the inorganic nano-particles in a polyvinyl alcohol solution having a certain high viscosity, so that the inorganic nano-particles can be dispersed in the modified layer more evenly.

In some embodiments, preparation of the component B includes the following steps: adding a cross-linking agent into water, stirring for 5 min to 15 min, and adjusting a pH value of the reaction system to a range of 0.8 to 3; preferably, stirring for 10 min.

In another aspect of the present disclosure, a modified polymer film is provided, and the modified polymer film is prepared by the methods in any one of the embodiments described herein. In the present disclosure, the modified polymer film includes a polymer layer and a modified layer which are composed together. The polymer layer and the modified layer are tightly adhered, so that the polarity of the surface of the non-polar polymer layer can be improved and maintained for a long time and the roughness of the polymer layer can be improved, and thus, application of the polymer layer can be broadened.

In another aspect of the present disclosure, a metallized polymer film is provided. The metallized polymer film includes a modified polymer film described herein, and a metal layer disposed on a modified layer of the modified polymer film. In a metallized polymer film of the present disclosure, the polymer layer and the metal layer are tightly adhered via the modified layer. After storing for a long time, the adhesion stress between the polymer layer and the metal payer will not obviously decrease. The metallized polymer film can be broadly used in various fields of packaging, printing or electronic components.

The present disclosure further provides use of the metallized polymer film disclosed above in preparing packaging materials, printing materials or electronic components.

The present disclosure is hereinafter described in further detail in connection with specific embodiments and proportions. For the experimental parameters not written in the following specific embodiments, reference is preferred to the guidelines given in the present disclosure, and reference may also be made to the experimental manuals in the field or other experimental methods known in the field, or to the experimental conditions recommended by the manufacturer. It is understood that the apparatus and raw materials used in the following embodiments are more specific, and may not be limited to this in other specific embodiments.

### Embodiment 1

Materials: a polymer film (substrate film) was a commercialized 6 μm polypropylene (PP) film: a raw material polyvinyl alcohol PVA had a weight-average molecular weight of 72000 Da and an alcoholysis degree of 99%; glutaraldehyde was a 50 wt.-% glutaraldehyde aqueous solution, having a purity of analytical grade: an acid was concentrated hydrochloric acid having a purity of analytical grade: nano-particles were titanium dioxide nano-particles, having a particle size in a range of 5 nm to 15 nm, and having a purity of analytical grade: and the surfactant was dodecyl sodium sulfate having a purity of analytical grade.

Preparation of liquid material was shown hereinafter. (1) Preparation of a first aqueous solution (10 kg) was shown hereinafter. Firstly, 100.00 g of PVA was weighted and added into 9890.00 g of pure water (at room temperature), stirred and soaked for 1 hour to 2 hours, and heated and stirred in a 90° C. oil bath until the PVA were totally dissolved after the soaking step. Then, 5.00 g of dodecyl sodium sulfate was added in the PVA solution, and stirred until the dodecyl sodium sulfate was totally dissolved. Finally, 5.00 g of titanium dioxide was added in the solution, mechanically stirred for 30 min, and subjected the resultant to ultrasonic dispersion in an ultrasonic cleaner for 60 min to form the first aqueous solution (power of the ultrasonic wave was 600 W, and frequency of the ultrasonic wave was 40 kHz). Components and concentrations of the first aqueous solution were: 1.0 wt.-% of PVA, 0.05 wt.-% of titanium dioxide, and 0.05 wt.-% of dodecyl sodium sulfate. (1) Preparation of a second aqueous solution (10 kg) was shown hereinafter. 200.00 g of glutaraldehyde was weighted and added in 9664.86 g of pure water and stirred for 10 min. Then, 135.14 g of concentrated hydrochloride acid was added in the solution formed above and stirred for 10 min. Components and concentrations of the second aqueous solution were: 1.0 wt.-% of glutaraldehyde, 0.50 wt.-% of hydrochloride acid, and a pH value of 0.86.

Corona treatment of the PP substrate film. A PP substrate film product was placed in a roll-to-roll corona treatment device. Power of the corona treatment was 10 KW, a current of the corona treatment was 6 A, and a linear velocity of the corona treatment was 50 m/min.

Modification of the PP substrate film with PVA. Firstly, the corona treated PP substrate was placed in a roll-to-roll coating device. A first aqueous phase and a second aqueous phase were loaded to two branches of the slit-type die head, respectively. Then, the first aqueous phase and the second aqueous phase were supplied at a rate of 70 mL/min, and a temperature of an oven was set as 80° C. Finally, the roll-to-roll coating device was operated at a speed of 5 m/min. In the whole process, the unwinding substrate was coated with a mixed solution of the first solution and the second solution while running through the slit-type die head, reacted in a platform region for 30 s, conveyed into an 80° C. oven, heated for 2.0 min, and rolled up. The coating thickness was 80 μm.

As a substrate film of the metallized film, a surface tension and a roughness were important performance indexes that affect subsequent processes. Surface tensions and roughness of a PP substrate film before and after modified with PVA were compared, and the results were shown in Table 1 hereinafter.

TABLE 1

| | Initial | | After stored for 3 months | |
|---|---|---|---|---|
| | Surface tension | Surface | Surface tension | Surface |
| Film | (mN/m) | roughness (nm) | (mN/m) | roughness (nm) |
| Polypropylene (PP) substrate | 30 | 75 | 30 | 76 |
| film | | | | |
| The film after corona treatment | 38 | 80 | 32 | 79 |
| The film after modified with | 60 | 90 | 59 | 91 |
| PVA | | | | |

The data above showed following: (1) After modified by the method in the present disclosure, the surface tension of the PP substrate film and the surface roughness of the PP substrate film significantly improved (that is, the surface tension of the PP substrate film improved by 100%, and the surface roughness of the PP substrate film improved by 20.0%), and the surface tension of the PP substrate film and the surface roughness of the PP substrate film were stable after stored for a period of time. The formed modified PP substrate film was more suitable for metalized treatment on the surface of the PP substrate film. (2) Compared to corona treatment in related art, improvement of the surface tension of the PP substrate film and improvement of the surface roughness of the PP substrate film were more obvious (on the basis of improvement of the corona treatment, the surface tension of the PP substrate film improved by 57.9%, and the surface roughness of the PP substrate film improved by 12.5%), and the surface tension of the PP substrate film and the surface roughness of the PP substrate film were more stable after stored for a period of time. The method of the present disclosure effectively solved the problem of unstable surface tension of the corona treated substrate in long term storage.

### Embodiment 2

Materials: a polymer film (substrate film) was a commercialized 6 μm polypropylene (PP) film: a rawmaterial polyvinyl alcohol PVA had a weight-average molecular weight of 90000 Da and an alcoholysis degree of 99%: glutaraldehyde was a 50 wt.-% glutaraldehyde aqueous solution, having a purity of analytical grade: an acid was concentrated sulfate acid having a purity of analytical grade: nano-particles were silicon dioxide nano-particles, having a particle size in a range of 5 nm to 15 nm, and having a purity of analytical grade; and the surfactant was sodium dodecyl benzene sulfonate having a purity of analytical grade.

Preparation of liquid material was shown hereinafter. (1) Preparation of a first aqueous solution (10 kg) was shown hereinafter. Firstly, 200.00 g of PVA was weighted and added into 9790.00 g of pure water (at room temperature), stirred and soaked for 1 hour to 2 hours, and heated and stirred in a 90° C. oil bath until the PVA were totally dissolved after the soaking step. Then, 5.00 g of sodium dodecyl benzene sulfonate was added in the PVA solution, and stirred until the sodium dodecyl benzene sulfonate was totally dissolved. Finally, 5.00 g of silicon dioxide was added in the solution, mechanically stirred for 30 min, and subjected the resultant to ultrasonic dispersion in an ultrasonic cleaner for 60 min to form the first aqueous solution (power of the ultrasonic wave was 600 W, and frequency of the ultrasonic wave was 40 kHz). Components and concentrations of the first aqueous solution were: 2.0 wt.-% of PVA, 0.05 wt.-% of silicon dioxide, and 0.05 wt.-% of sodium dodecyl benzene sulfonate. (1) Preparation of a second aqueous solution (10 kg) was shown hereinafter. 400.00 g of glutaraldehyde was weighted and added in 9549.14 g of pure water and stirred for 10 min. Then, 50.86g of concentrated sulfate acid was added in the solution formed above and stirred for 10 min. Components and concentrations of the second aqueous solution were: 2.0 wt.-% of glutaraldehyde, 0.50 wt.-% of sulfate acid, and a pH value of 0.99.

Corona treatment of the PP substrate film. A PP substrate film product was placed in a roll-to-roll corona treatment device. Power of the corona treatment was 20 kW, a current of the corona treatment was 8 A, and a linear velocity of the corona treatment was 80 m/min.

Modification of the PP substrate film with PVA. Firstly, the corona treated PP substrate was placed in a roll-to-roll coating device. A first aqueous phase and a second aqueous phase were loaded to two branches of the slit-type die head respectively. Then, the first aqueous phase and the second aqueous phase were supplied at a rate of 87.5 mL/min, and a temperature of an oven was set as 80° C. Finally, the roll-to-roll coating device was operated at a speed of 5 m/min. In the whole process, the unwinding substrate was coated with a mixed solution of the first solution and the second solution while running through the slit-type die head, reacted in a platform region for 30 s, conveyed into an 80° C. oven, heated for 2.0 min, and rolled up. The coating thickness was 100 μm.

As a substrate film of the metallized film, a surface tension and a roughness were important performance indexes that affect subsequent processes. Surface tensions and roughness of a PP substrate film before and after modified with PVA were compared, and the results were shown in Table 2 hereinafter.

TABLE 2

| | Initial | | After stored for 3 months | |
|---|---|---|---|---|
| | Surface tension | Surface | Surface tension | Surface |
| Film | (mN/m) | roughness (nm) | (mN/m) | roughness (nm) |
| Polypropylene (PP) substrate | 30 | 75 | 30 | 76 |
| film | | | | |
| The film after corona treatment | 42 | 83 | 34 | 80 |
| The film after modified with | 65 | 92 | 63 | 94 |
| PVA | | | | |

The data above showed following: (1) After modified by the method in the present disclosure, the surface tension of the PP substrate film and the surface roughness of the PP substrate film significantly improved (that is, the surface tension of the PP substrate film improved by 116.7%, and the surface roughness of the PP substrate film improved by 22.7%), and the surface tension of the PP substrate film and the surface roughness of the PP substrate film were stable after stored for a period of time. The formed modified PP substrate film was more suitable for metalized treatment on the surface of the PP substrate film. (2) Compared to corona treatment in related art, improvement of the surface tension of the PP substrate film and improvement of the surface roughness of the PP substrate film were more obvious (on the basis of improvement of the corona treatment, the surface tension of the PP substrate film improved by 54.8%, and the surface roughness of the PP substrate film improved by 10.8%), and the surface tension of the PP substrate film and the surface roughness of the PP substrate film were more stable after stored for a period of time. The method of the present disclosure effectively solved the problem of unstable surface tension of the corona treated substrate in long term storage.

### Embodiment 3

Materials: a polymer film (substrate film) was a commercialized 4.5 μm polypropylene (PP) film: a raw material polyvinyl alcohol PVA had a weight-average molecular weight of 145000 Da and an alcoholysis degree of 99%; glutaraldehyde was a 50 wt.-% glutaraldehyde aqueous solution, having a purity of analytical grade; an acid was concentrated sulfate acid having a purity of analytical grade: nano-particles were titanium dioxide nano-particles, having a particle size in a range of 5 nm to 15 nm, and having a purity of analytical grade: and the surfactant was Tween® 80 having a purity of analytical grade.

Preparation of liquid material was shown hereinafter. (1) Preparation of a first aqueous solution (10 kg) was shown hereinafter. Firstly, 100.00 g of PVA was weighted and added into 9886.00 g of pure water (at room temperature), stirred and soaked for 1 hour to 2 hours, and heated and stirred in a 90° C. oil bath until the PVA were totally dissolved after the soaking step. Then, 6.00 g of Tween® 80 was added in the PVA solution, and stirred until the Tween® 80 was totally dissolved. Finally, 8.00 g of titanium dioxide was added in the solution, mechanically stirred for 30 min, and subjected the resultant to ultrasonic dispersion in an ultrasonic cleaner for 70 min to form the first aqueous solution (power of the ultrasonic wave was 600 W, and frequency of the ultrasonic wave was 40 kHz). Components and concentrations of the first aqueous solution were: 1.0 wt.-% of PVA, 0.08 wt.-% of titanium dioxide, and 0.06 wt.-% of Tween® 80. (1) Preparation of a second aqueous solution (10 kg) was shown hereinafter. 300.00 g of glutaraldehyde was weighted and added in 9669.48 g of pure water and stirred for 10 min. Then, 30.52 g of concentrated sulfate acid was added in the solution formed above and stirred for 10 min. Components and concentrations of the second aqueous solution were: 1.5 wt.-% of glutaraldehyde, 0.30 wt.-% of sulfate acid, and a pH value of 1.2.

Corona treatment of the PP substrate film. A PP substrate film product was placed in a roll-to-roll corona treatment device. Power of the corona treatment was 10 kW, a current of the corona treatment was 6 A, and a linear velocity of the corona treatment was 50 m/min.

Modification of the PP substrate film with PVA. Firstly, the corona treated PP substrate was placed in a roll-to-roll coating device. A first aqueous phase and a second aqueous phase were loaded to two branches of the slit-type die head respectively. Then, the first aqueous phase and the second aqueous phase were supplied at a rate of 175 mL/min, and a temperature of an oven was set as 80° C. Finally, the roll-to-roll coating device was operated at a speed of 5 m/min. In the whole process, the unwinding substrate was coated with a mixed solution of the first solution and the second solution while running through the slit-type die head, reacted in a platform region for 30 s, conveyed into an 80° C. oven, heated for 2.0 min, and rolled up. The coating thickness was 200 μm.

As a substrate film of the metallized film, a surface tension and a roughness were important performance indexes that affect subsequent processes. Surface tensions and roughness of a PP substrate film before and after modified with PVA were compared, and the results were shown in Table 3 hereinafter.

TABLE 3

| | Initial | | After stored for 3 months | |
|---|---|---|---|---|
| | Surface tension | Surface | Surface tension | Surface |
| Film | (mN/m) | roughness (nm) | (mN/m) | roughness (nm) |
| Polypropylene (PP) substrate | 30 | 75 | 30 | 76 |
| film | | | | |
| The film after corona treatment | 39 | 78 | 33 | 77 |
| The film after modified with | 66 | 95 | 65 | 96 |
| PVA | | | | |

The data above showed following: (1) After modified by the method in the present disclosure, the surface tension of the PP substrate film and the surface roughness of the PP substrate film significantly improved (that is, the surface tension of the PP substrate film improved by 120.0%, and the surface roughness of the PP substrate film improved by 26.7%), and the surface tension of the PP substrate film and the surface roughness of the PP substrate film were stable after stored for a period of time. The formed modified PP substrate film was more suitable for metalized treatment on the surface of the PP substrate film. (2) Compared to corona treatment in related art, improvement of the surface tension of the PP substrate film and improvement of the surface roughness of the PP substrate film were more obvious (on the basis of improvement of the corona treatment, the surface tension of the PP substrate film improved by 69.2%, and the surface roughness of the PP substrate film improved by 21.8%), and the surface tension of the PP substrate film and the surface roughness of the PP substrate film were more stable after stored for a period of time. The method of the present disclosure effectively solved the problem of unstable surface tension of the corona treated substrate in long term storage.

### Embodiment 4

Materials: a polymer film (substrate film) was a commercialized 6 μm polyethylene terephthalate (PET) film: a raw material polyvinyl alcohol PVA had a weight-average molecular weight of 72000 Da and an alcoholysis degree of 99%: glutaraldehyde was a 50 wt.-% glutaraldehyde aqueous solution, having a purity of analytical grade: an acid was concentrated hydrochloric acid having a purity of analytical grade: nano-particles were titanium dioxide nano-particles, having a particle size in a range of 5 nm to 15 nm, and having a purity of analytical grade: and the surfactant was dodecyl sodium sulfate having a purity of analytical grade.

Preparation of liquid material was shown hereinafter. (1) Preparation of a first aqueous solution (10 kg) was shown hereinafter. Firstly, 100.00 g of PVA was weighted and added into 9890.00 g of pure water (at room temperature), stirred and soaked for 1 hour to 2 hours, and heated and stirred in a 90° C. oil bath until the PVA were totally dissolved after the soaking step. Then, 5.00 g of dodecyl sodium sulfate was added in the PVA solution, and stirred until the dodecyl sodium sulfate was totally dissolved. Finally, 5.00 g of titanium dioxide was added in the solution, mechanically stirred for 30 min, and subjected the resultant to ultrasonic dispersion in an ultrasonic cleaner for 60 min to form the first aqueous solution (power of the ultrasonic wave was 600 W, and frequency of the ultrasonic wave was 40 kHz). Components and concentrations of the first aqueous solution were: 1.0 wt.-% of PVA, 0.05 wt.-% of titanium dioxide, and 0.05 wt.-% of dodecyl sodium sulfate. (1) Preparation of a second aqueous solution (10 kg) was shown hereinafter. 200.00 g of glutaraldehyde was weighted and added in 9664.86 g of pure water and stirred for 10 min. Then, 135.14 g of concentrated hydrochloride acid was added in the solution formed above and stirred for 10 min. Components and concentrations of the second aqueous solution were: 1.0 wt.-% of glutaraldehyde, 0.50 wt.-% of hydrochloride acid, and a pH value of 0.86.

Corona treatment of the PET substrate film. A PET substrate film product was placed in a roll-to-roll corona treatment device. Power of the corona treatment was 10 kW, a current of the corona treatment was 6 A, and a linear velocity of the corona treatment was 50 m/min.

Modification of the PET substrate film with PVA. Firstly, the corona treated PET substrate was placed in a roll-to-roll coating device. A first aqueous phase and a second aqueous phase were loaded to two branches of the slit-type die head respectively. Then, the first aqueous phase and the second aqueous phase were supplied at a rate of 70 mL/min, and a temperature of an oven was set as 80° C. Finally, the roll-to-roll coating device was operated at a speed of 5 m/min. In the whole process, the unwinding substrate was coated with a mixed solution of the first solution and the second solution while running through the slit-type die head, reacted in a platform region for 30 s, conveyed into an 80° C. oven, heated for 2.0 min, and rolled up. The coating thickness was 80 μm.

As a substrate film of the metallized film, a surface tension and a roughness were important performance indexes that affect subsequent processes. Surface tensions and roughness of a PET substrate film before and after modified with PVA were compared, and the results were shown in Table 4 hereinafter.

TABLE 4

| | Initial | | After stored for 3 months | |
|---|---|---|---|---|
| | Surface tension | Surface | Surface tension | Surface |
| Film | (mN/m) | roughness (nm) | (mN/m) | roughness (nm) |
| PET substrate film | 35 | 80 | 36 | 82 |
| The film after corona treatment | 42 | 83 | 37 | 80 |
| The film after modified with | 68 | 94 | 69 | 96 |
| PVA | | | | |

The data above showed following: (1) After modified by the method in the present disclosure, the surface tension of the PET substrate film and the surface roughness of the PET substrate film significantly improved (that is, the surface tension of the PET substrate film improved by 94.3%, and the surface roughness of the PET substrate film improved by 17.5%), and the surface tension of the PET substrate film and the surface roughness of the PET substrate film were stable after stored for a period of time. The formed modified PET substrate film was more suitable for metalized treatment on the surface of the PET substrate film. (2) Compared to corona treatment in related art, improvement of the surface tension of the PET substrate film and improvement of the surface roughness of the PET substrate film were more obvious (on the basis of improvement of the corona treatment, the surface tension of the PET substrate film improved by 61.9%, and the surface roughness of the PET substrate film improved 13.3%), and the surface tension of the PET substrate film and the surface roughness of the PET substrate film were more stable after stored for a period of time. The method of the present disclosure effectively solved the problem of unstable surface tension of the corona treated substrate in long term storage.

### Embodiment 5

Materials: a polymer film (substrate film) was a commercialized 6 μm polybutylene terephthalate (PBT) film: a raw material polyvinyl alcohol PVA had a weight-average molecular weight of 72000 Da and an alcoholysis degree of 99%; glutaraldehyde was a 50 wt.-% glutaraldehyde aqueous solution, having a purity of analytical grade: an acid was concentrated hydrochloric acid having a purity of analytical grade: nano-particles were titanium dioxide nano-particles, having a particle size in a range of 5 nm to 15 nm, and having a purity of analytical grade: and the surfactant was dodecyl sodium sulfate having a purity of analytical grade.

Preparation of liquid material was shown hereinafter. (1) Preparation of a first aqueous solution (10 kg) was shown hereinafter. Firstly, 100.00 g of PVA was weighted and added into 9890.00 g of pure water (at room temperature), stirred and soaked for 1 hour to 2 hours, and heated and stirred in a 90° C. oil bath until the PVA were totally dissolved after the soaking step. Then, 5.00 g of dodecyl sodium sulfate was added in the PVA solution, and stirred until the dodecyl sodium sulfate was totally dissolved. Finally, 5.00 g of titanium dioxide was added in the solution, mechanically stirred for 30 min, and subjected the resultant to ultrasonic dispersion in an ultrasonic cleaner for 60 min to form the first aqueous solution (power of the ultrasonic wave was 600 W, and frequency of the ultrasonic wave was 40 kHz). Components and concentrations of the first aqueous solution were: 1.0 wt.-% of PVA, 0.05 wt.-% of titanium dioxide, and 0.05 wt.-% of dodecyl sodium sulfate. (1) Preparation of a second aqueous solution (10 kg) was shown hereinafter. 200.00 g of glutaraldehyde was weighted and added in 9745.94 g of pure water and stirred for 10 min. Then, 54.06 g of concentrated hydrochloride acid was added in the solution formed above and stirred for 10 min. Components and concentrations of the second aqueous solution were: 1.0 wt.-% of glutaraldehyde, 0.20 wt.-% of hydrochloride acid, and a pH value of 1.26.

Corona treatment of the PBT substrate film. A PBT substrate film product was placed in a roll-to-roll corona treatment device. Power of the corona treatment was 10 kW, a current of the corona treatment was 6 A, and a linear velocity of the corona treatment was 50 m/min.

Modification of the PBT substrate film with PVA. Firstly, the corona treated PBT substrate was placed in a roll-to-roll coating device. A first aqueous phase and a second aqueous phase were loaded to two branches of the slit-type die head respectively. Then, the first aqueous phase and the second aqueous phase were supplied at a rate of 70 mL/min, and a temperature of an oven was set as 80° C. Finally, the roll-to-roll coating device was operated at a speed of 5 m/min. In the whole process, the unwinding substrate was coated with a mixed solution of the first solution and the second solution while running through the slit-type die head, reacted in a platform region for 30 s, conveyed into an 80° C. oven, heated for 2.0 min, and rolled up. The coating thickness was 80 μm.

As a substrate film of the metallized film, a surface tension and a roughness were important performance indexes that affect subsequent processes. Surface tensions and roughness of a PBT substrate film before and after modified with PVA were compared, and the results were shown in Table 5 hereinafter.

TABLE 5

| | Initial | | After stored for 3 months | |
|---|---|---|---|---|
| | Surface tension | Surface | Surface tension | Surface |
| Films | (mN/m) | roughness (nm) | (mN/m) | roughness (nm) |
| PET substrate film | 36 | 79 | 34 | 81 |
| The film after corona treatment | 44 | 83 | 37 | 79 |
| The film after modified with | 67 | 92 | 68 | 94 |
| PVA | | | | |

The data above showed following: (1) After modified by the method in the present disclosure, the surface tension of the PBT substrate film and the surface roughness of the PBT substrate film significantly improved (that is, the surface tension of the PBT substrate film improved by 86.1%, and the surface roughness of the PBT substrate film improved by 16.5%), and the surface tension of the PBT substrate film and the surface roughness of the PBT substrate film were stable after stored for a period of time. The formed modified PBT substrate film was more suitable for metalized treatment on the surface of the PBT substrate film. (2) Compared to corona treatment in related art, improvement of the surface tension of the PBT substrate film and improvement of the surface roughness of the PBT substrate film were more obvious (on the basis of improvement of the corona treatment, the surface tension of the PBT substrate film improved by 52.3%, and the surface roughness of the PBT substrate film improved by 10.8%), and the surface tension of the PBT substrate film and the surface roughness of the PBT substrate film were more stable after stored for a period of time. The method of the present disclosure effectively solved the problem of unstable surface tension of the corona treated substrate in long term storage.

### Embodiment 6

Materials: a polymer film (substrate film) was a commercialized 6 μm polyethylene naphthalate (PEN) film: a material polyvinyl alcohol PVA had a weight-average molecular weight of 72000 Da and an alcoholysis degree of 99%; glutaraldehyde was a 50 wt.-% glutaraldehyde aqueous solution, having a purity of analytical grade: an acid was concentrated hydrochloric acid having a purity of analytical grade: nano-particles were titanium dioxide nano-particles, having a particle size in a range of 5 nm to 15 nm, and having a purity of analytical grade: and the surfactant was dodecyl sodium sulfate having a purity of analytical grade.

Preparation of liquid material was shown hereinafter. (1) Preparation of a first aqueous solution (10 kg) was shown hereinafter. Firstly, 100.00 g of PVA was weighted and added into 9890.00 g of pure water (at room temperature), stirred and soaked for 1 hour to 2 hours, and heated and stirred in a 90° C. oil bath until the PVA were totally dissolved after the soaking step. Then, 5.00 g of dodecyl sodium sulfate was added in the PVA solution, and stirred until the dodecyl sodium sulfate was totally dissolved. Finally, 5.00 g of titanium dioxide was added in the solution, mechanically stirred for 30 min, and subjected the resultant to ultrasonic dispersion in an ultrasonic cleaner for 60 min to form the first aqueous solution (power of the ultrasonic wave was 600 W, and frequency of the ultrasonic wave was 40 kHz). Components and concentrations of the first aqueous solution were: 1.0 wt.-% of PVA, 0.05 wt.-% of titanium dioxide, and 0.05 wt.-% of dodecyl sodium sulfate. (1) Preparation of a second aqueous solution (10 kg) was shown hereinafter. 200.00 g of glutaraldehyde was weighted and added in 9732.43 g of pure water and stirred for 10 min. Then, 67.57 g of concentrated hydrochloride acid was added in the solution formed above and stirred for 10 min. Components and concentrations of the second aqueous solution were: 1.0 wt.-% of glutaraldehyde, 0.25 wt.-% of hydrochloride acid, and a pH value of 1.16.

Corona treatment of the PEN substrate film. A PEN substrate film product was placed in a roll-to-roll corona treatment device. Power of the corona treatment was 10 kW, a current of the corona treatment was 6 A, and a linear velocity of the corona treatment was 50 m/min.

Modification of the PEN substrate film with PVA. Firstly, the corona treated PEN substrate was placed in a roll-to-roll coating device. A first aqueous phase and a second aqueous phase were loaded to two branches of the slit-type die head respectively. Then, the first aqueous phase and the second aqueous phase were supplied at a rate of 70 mL/min, and a temperature of an oven was set as 80° C. Finally, the roll-to-roll coating device was operated at a speed of 5 m/min. In the whole process, the unwinding substrate was coated with a mixed solution of the first solution and the second solution while running through the slit-type die head, reacted in a platform region for 30 s, conveyed into an 80° C. oven, heated for 2.0 min, and rolled up. The coating thickness was 80 μm.

As a substrate film of the metallized film, a surface tension and a roughness were important performance indexes that affect subsequent processes. Surface tensions and roughness of a PEN substrate film before modified with PVA and after modified with PVA were compared, and the results were shown in Table 6 hereinafter.

TABLE 6

| | Initial | | After stored for 3 months | |
|---|---|---|---|---|
| | Surface tension | Surface | Surface tension | Surface |
| Film | (mN/m) | roughness (nm) | (mN/m) | roughness (nm) |
| PEN substrate film | 34 | 78 | 34 | 80 |
| The film after corona treatment | 41 | 82 | 35 | 80 |
| The film after modified with | 66 | 91 | 65 | 92 |
| PVA | | | | |

The data above showed following: (1) After modified by the method in the present disclosure, the surface tension of the PEN substrate film and the surface roughness of the PEN substrate film significantly improved (that is, the surface tension of the PEN substrate film improved by 94.1%, and the surface roughness of the PEN substrate film improved by 16.7%), and the surface tension of the PEN substrate film and the surface roughness of the PEN substrate film were stable after stored for a period of time. The formed modified PEN substrate film was more suitable for metalized treatment on the surface of the PEN substrate film. (2) Compared to corona treatment in related art, improvement of the surface tension of the PEN substrate film and improvement of the surface roughness of the PEN substrate film were more obvious (on the basis of improvement of the corona treatment, the surface tension of the PEN substrate film improved by 61.0%, and the surface roughness of the PEN substrate film improved by 11.0%), and the surface tension of the PEN substrate film and the surface roughness of the PEN substrate film were more stable after stored for a period of time. The method of the present disclosure effectively solved the problem of unstable surface tension of the corona treated substrate in long term storage.

### Embodiment 7

Embodiment 7 was basically the same with Embodiment 4. Differences between the Embodiment 7 and Embodiment 4 were that titanium dioxide was not added in the first aqueous solution.

TABLE 7

| | Initial | | After stored for 3 months | |
|---|---|---|---|---|
| | Surface tension | Surface | Surface tension | Surface |
| Film | (mN/m) | roughness (nm) | (mN/m) | roughness (nm) |
| PET substrate film | 35 | 80 | 36 | 82 |
| The film after corona treatment | 42 | 83 | 37 | 80 |
| The film after modified with | 59 | 85 | 60 | 84 |
| PVA | | | | |

The data above showed following: (1) After modified by the method in the present disclosure, the surface tension of the PET substrate film and the surface roughness of the PET substrate film significantly improved (that is, the surface tension of the PET substrate film improved by 68.6%, and the surface roughness of the PET substrate film improved by 6.3%), and the surface tension of the PET substrate film and the surface roughness of the PET substrate film were stable after stored for a period of time. The formed modified PET substrate film was more suitable for metalized treatment on the surface of the PET substrate film. (2) Compared to corona treatment in related art, improvement of the surface tension of the PET substrate film was more obvious (on the basis of improvement of the corona treatment, the surface tension of the PET substrate film improved by 40.5%), and the surface tension of the PET substrate film was more stable after stored for a period of time. The method of the present disclosure effectively solved the problem of unstable surface tension of the corona treated substrate in long term storage.

### Comparative Embodiment 1

Comparative Embodiment 1 was basically the same with the Embodiment 1. Differences between Comparative Embodiment 1 and the Embodiment 4 were that the concentration of the polyvinyl alcohol in the first aqueous solution was 5.0 wt.-%, and the concentration of the glutaraldehyde in the second aqueous solution was 5.0 wt-%.

### Comparative Embodiment 2

The Comparative Embodiment 2 was basically the same with Embodiment 4. Difference between Comparative Embodiment 2 and Embodiment 4 was that the substrate film was modified with the first aqueous solution.

### Comparative Embodiment 3

Comparative Embodiment 3 was basically the same with Embodiment 4. Difference between Comparative Embodiment 3 and Embodiment 4 was that the polyvinyl alcohol was replaced with a polyester resin.

### Comparative Embodiment 4

Comparative Embodiment 4 was basically the same with Embodiment 4. Difference between Comparative Embodiment 4 and Embodiment 4 was that the polyvinyl alcohol was replaced with a polyacrylate resin.

### Comparative Embodiment 5

Comparative Embodiment 5 was basically the same with Embodiment 4. Difference between Comparative Embodiment 5 and Embodiment 4 was that mass concentration of the glutaraldehyde in the second aqueous solution was 0.1%.

### Test and characterization

(1) Surface tension: surface tension of a polymer film was a key factor affecting surface adhesion properties of the polymer film. The purpose of preparing a modified polymer film on a surface of the modified polymer as described above is to improve the surface tension of polymer film, so as to improve the surface adhesion properties of the polymer film. In this disclosure, with reference to GB/T14216-2008, the surface tension of the prepared polymer film and the surface tension of the prepared polymer film after stored 3 months were tested.

(2) Surface roughness: improvement of surface roughness can improve the surface adhesion properties of the modified polymer film. In the present disclosure, the roughness of the prepared polymer film was tested with reference to the national standard GB/T31227-2014.

(3) Surface adhesion properties: in order to verify the adhesion properties of the polymer film, a 1 μum-thick aluminum layer were plated on surfaces of substrate films by physical vapor deposition respectively, to form metallized polymer film. The substrate film were a PET film without corona treatment, corona treated PET film, the modified polymer films prepared in Embodiment 4 and Comparative Embodiment Ito the Comparative Embodiment 5. Then the adhesion stress between the substrate film and the metal layer of the prepared metallized polymer film was tested by a following method. A 1 mm aluminum foil was bonded with a layer of PermacelP-94 double-sided adhesive tape, the metallized polymer film was bonded on the double-sided adhesive tape, and a layer of vinyl acrylate copolymer film (DuPont Nurcel0903, having a thickness of 50 μm) was covered on the metallized polymer film. Then the formed film was subjected to hot pressing under conditions of 1.3×10⁵ N/m² and 120° C. for 10 s, cooled to room temperature, and cut into small strips of 150 mm×15 mm. Finally, a vinyl acrylate copolymer film of a small strip sample was fastened with upper fixtures of a tensile machine, and the rest of the small strip sample was fixed in the lower fixture. After fixing, the substrate film and the metal layer were peeled off at an angle of 180° and at a speed of 100 m m/min, and the peeling force (i.e., the adhesion between the polymer film and the metal layer) was tested.

(4) Stability of the coating layer.

(1) Thermal stability of the polymer film: the prepared modified polymer film was heated in a 150° C. oven for 30 min, and the surface tension of the heated polymer film and the roughness of the heated polymer film were tested.

(2) Stability of the polymer film in an aqueous solution: firstly, the prepared modified polymer film were placed in 80° C. hot water for 24 hours; then the polymer film were dried in a 60° C. oven; and finally, the surface tension of the dried polymer film and the roughness of the dried polymer film were tested.

Performance test results of the modified polymer film prepared in Comparative Embodiment 1 to Comparative Embodiment 5 were shown in Table 8.

TABLE 8

| | Initial | | After stored for 3 months | |
|---|---|---|---|---|
| | Surface | Surface | Surface | Surface |
| | tension | roughness | tension | roughness |
| Film | (mN/m) | (nm) | (mN/m) | (nm) |
| PET substrate film | 35 ± 1.0 | 80 ± 2.0 | 36 ± 1.5 | 82 ± 1.0 |
| The PET film after a | 42 ± 5.0 | 83 ± 3.0 | 37 ± 1.0 | 80 ± 2.0 |
| corona treatment | | | | |
| Embodiment 4 | 68 ± 1.0 | 94 ± 1.5 | 69 ± 1.2 | 96 ± 1.0 |
| Comparative | 63 ± 6.0 | 97 ± 5.0 | 56 ± 5.0 | 98 ± 5.0 |
| Embodiment 1 | | | | |
| Comparative | 66 ± 2.0 | 95 ± 2.0 | 55 ± 5.0 | 96 ± 5.0 |
| Embodiment 2 | | | | |
| Comparative | 55 ± 2.0 | 81 ± 2.0 | 53 ± 2.2 | 82 ± 3.0 |
| Embodiment 3 | | | | |
| Comparative | 56 ± 1.5 | 79 ± 1.8 | 52 ± 2.8 | 83 ± 3.1 |
| Embodiment 4 | | | | |
| Comparative | 65 ± 5.0 | 90 ± 6.0 | 64 ± 6.0 | 89 ± 5.0 |
| Embodiment 5 | | | | |

TABLE 9

| | After dried at a temperature | | After treated in hot water | | After the polymer |
|---|---|---|---|---|---|
| | of 150° C. for 30 min | | at 80° C. for 24 hours | | film is metallized |
| | Surface | Surface | Surface | Surface | Adhesion stress between the |
| | tension | roughness | tension | roughness | modified polymer film and |
| Film | (mN/m) | (nm) | (mN/m) | (nm) | the metal layer (N/cm) |
| PET substrate film | 36 ± 1.0 | 81 ± 2.0 | 35 ± 1.0 | 79 ± 2.0 | 0.7 |
| The PET film after a | 39 ± 4.0 | 79 ± 3.0 | 36 ± 3.0 | 78 ± 2.0 | 0.9 |
| corona treatment | | | | | |
| Embodiment 4 | 68 ± 1.2 | 95 ± 1.0 | 67 ± 1.0 | 93 ± 1.3 | 3.0 |
| Comparative | 50 ± 6.0 | 97 ± 4.0 | 43 ± 7.0 | 96 ± 5.0 | 1.7 |
| Embodiment 1 | | | | | |
| Comparative | 45 ± 5.0 | 90 ± 6.0 | 36 ± 2.0 | 80 ± 2.5 | 1.4 |
| Embodiment 2 | | | | | |
| Comparative | 48 ± 4.0 | 80 ± 5.0 | 38 ± 5.0 | 81 ± 4.0 | 1.2 |
| Embodiment 3 | | | | | |
| Comparative | 46 ± 5.0 | 82 ± 4.0 | 35 ± 3.0 | 79 ± 3.0 | 1.3 |
| Embodiment 4 | | | | | |
| Comparative | 47 ± 6.0 | 91 ± 5.0 | 39 ± 3.0 | 80 ± 2.0 | 1.1 |
| Embodiment 5 | | | | | |

It can be learnt from Table 8 that, since concentration of polyvinyl alcohol and glutaraldehyde in Comparative Embodiment 1 were unduly high, the modifier is hard to be coated evenly in the coating step and the surface tension of the prepared modified layer and the roughness of the prepared modified layer were not uniform. Compared to Embodiment 4, the initial surface tension of the modified layer of Comparative Embodiment 1 is lower, the performances of the modified layer of Comparative Embodiment 1 was not stable, and the surface tension of the modified layer of Comparative Embodiment 1 clearly decreased after stored for 3 months. Cross-linking agent was not added in Comparative Embodiment 2, the prepared modified layer was not stable enough. Although initial surface tension of the modified layer of Comparative Embodiment 2 is similar to that of the modified layer prepared in Embodiment 4, the surface tension of Comparative Embodiment 2 significantly decreased after stored for a long term, and the surface tension of the modified layer prepared in Comparative Embodiment 2was not uniform. In Comparative Embodiment 3 and Comparative Embodiment 4, the polyvinyl alcohol was replaced with a polyester resin and a polyacrylate resin to modify the polymer film. Improvement of the surface tension of the polyester resin and the polyacrylate resin was not as good as than the polyvinyl alcohol. In addition, since formulation of the modifier was designed based on polyvinyl alcohol, cross-linking degree of the formed modified layer changed after the polyvinyl alcohol was replaced with other resins, and the stability of the formed modified layer decreased. Thus, surface tension of the prepared modified polymer film decreased to some extent after stored for a period of time.

It can be concluded from Table 9 that, compared to Embodiment 4, the surface modified layer in Comparative Embodiment Ito Comparative Embodiment 5 were not stable, resulting in relative low adhesion stress between the substrate film and the metal layer of the metallized polymer film.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure.

The above-described embodiments are only several implementations of the present disclosure, and the descriptions are relatively specific and detailed, but they should not be construed as limiting the scope of the present disclosure. It should be understood by those of ordinary skill in the art that various modifications and improvements can be made without departing from the concept of the present disclosure, and all fall within the protection scope of the present disclosure. Therefore, the patent protection of the present disclosure shall be defined by the appended claims.

1. A method for preparing a modified polymer film, comprising the following steps:
providing a polymer layer, and subjecting the polymer layer to a corona treatment to form a corona treated polymer layer; and
coating a modifier on a surface of the corona treated polymer layer, and drying to form a modified layer,
wherein a material of the polymer layer is one or more selected from polyethylene, polypropylene, polyethylene terephthalate, polybutylene terephthalate, polyethylene naphthalate, polyvinyl chloride, polyvinylidene fluoride, and polyphenylene sulfide;
wherein the modifier comprises a component A and a component B which are separately prepared, wherein the component A is an aqueous solution of polyvinyl alcohol having 0.2% to 2% by mass of polyvinyl alcohol, and the polyvinyl alcohol has an alcoholysis degree in a range of 95% to 100%; and
wherein the component B is an aqueous solution of a cross-linking agent having 0.2% to 2% by mass of the cross-linking agent, and the cross-linking agent is one or more selected from glyoxal, malondialdehyde, butanedial, glutaraldehyde, hexanedial, heptanedial, and octanedial.

2. The method of claim 1, wherein in the step of coating the modifier on the surface of the corona treated polymer layer, the ratio of a feeding amount of the component A to a feeding amount of the component B is in a range of 1:4 to 4:1.

3. The method of claim 1, wherein the component A further comprises 0.001% to 0.2% by mass of inorganic nano-particles, and the inorganic nano-particles are one or more selected from titanium dioxide, silicon dioxide, and graphene oxide; and/or,
the component A further comprises 0.001% to 0.1% by mass of a surfactant, and the surfactant is one or more selected from dodecyl sodium sulfate, sodium dodecyl sulfonate, Tween® 20, and Tween® 80.

4. The method of claim 1, wherein a pH value of the component B is in a range of 0.8 to 3.

5. The method of claim 3, wherein an average particle size of the inorganic particles is in a range of 5 nm to 15 nm.

6. The method of claim 1, wherein a weight-average molecular weight of the polyvinyl alcohol is in a range of 50000 Da to 150000 Da.

7. The method of claim 1, wherein in the step of coating the modifier on the surface of the corona treated polymer layer, a coating thickness of the modifier is in a range of 20 μm to 200 μm; and/or,
a thickness of the formed modified layer is in a range of 20 nm to 200 nm.

8. The method of claim 1, wherein the time interval between a step of coating the modifier on the surface of the corona treated polymer layer and a step of drying is in a range of 0 to 120 seconds; and/or,
the step of drying is a heating treatment, wherein a temperature of the heating treatment is in a range of 60° C. to 90° C., and a time of the heating treatment is in a range of 0.01 min to 5 min.

9. The method of claim 1, wherein the step of coating the modifier on the surface of the corona treated polymer layer comprises:
separately loading the component A and the component B into different feeding devices, respectively; and
feeding the component A and the component B synchronously from the respective feeding devices at a rate of 50 mL/min to 200 mL/min for coating.

10. The method of claim 1, wherein in the step of subjecting the polymer layer to a corona treatment to form a corona treated polymer layer, the power of the corona treatment is in a range of 10 kW to 30 kW, the current of the corona treatment is in a range of 4 A to 10 A, and the linear velocity of the corona treatment is in a range of 50 m/min to 200 m/min.

11. A modified polymer film, prepared by the method of claim 1.

12. A metallized polymer film, comprising:
the modified polymer film of claim 11, and
a metal layer disposed on the modified layer of the modified polymer film.

13. A method of preparing packaging materials, printing products or electronic components, comprising using the metallized polymer film of claim 12.
